(19) United States
(12) Patent Application Publication
(10) Pub. No.: US 2024/0407084 A1
(43) Pub. Date: Dec. 5, 2024

(54) ARRAY SUBSTRATE, DISPLAY PANEL AND DISPLAY DEVICE

(71) Applicant: HKC CORPORATION LIMITED, Shenzhen (CN)

(72) Inventors: Yao LI, Shenzhen (CN); Zhonglin CAO, Shenzhen (CN); Chuan WU, Shenzhen (CN); Lidan YE, Shenzhen (CN)

(73) Assignee: HKC CORPORATION LIMITED, Shenzhen (CN)

(21) Appl. No.: 18/662,848

(22) Filed: May 13, 2024

(30) Foreign Application Priority Data
May 31, 2023 (CN) 202310638976.0

(51) Int. Cl. H05K 1/02; H01L 23/498; H05K 1/18

(52) U.S. Cl. CPC H05K 1/0296; H01L 23/498; H05K 1/18; H05K 2201/09027; H05K 2201/09063; H05K 2201/10378

(57) ABSTRACT

Disclosed are an array substrate, a display panel and a display device. The array substrate has a circular display region, the display region is provided with data lines and scan lines, and the data lines and the scan lines are insulated and intersected. There are at least two data lines, each of the data lines extends along a radial direction of the display region, and the data lines are distributed at intervals along a circumferential direction of the display region. There are at least two circular scanning lines, the scanning lines are provided concentrically and distributed along the radial direction of the display region.

### CROSS-REFERENCE TO RELATED APPLICATIONS

This application claims priority to Chinese Patent Application No. 202310638976.0, filed on May 31, 2023, the entire contents of which are incorporated herein by reference.

### TECHNICAL FIELD

The present application relates to the technical field of displays, and in particular to an array substrate, a display panel using the array substrate and a display device using the display panel.

### BACKGROUND

A circular display screen with a center hole is widely used in devices that require a pointer in the center of the screen, such as mechanical pointer watches, oil dials or the like. This type of screen has a shape close to a pure circle, and requires a hole of a certain size in the center for placing the pointer or other mechanical devices. However, this type of screen still use the traditional pixel arrangement, that is, the scanning lines are horizontal, and the data lines are vertical. Due to the limitations of the circular shape and the center hole, the length of different data lines varies greatly, which can lead to different loads on each date line. When driven at the same voltage, the actual voltage on each data line will vary due to the different loads on each data line, resulting in different display brightness.

In order to solve this problem, in the traditional design, the shorter data lines passing through the display region are wound outside the display region to compensate for the lack of load, which not only increases redundant lines, but also significantly increases the lower frame outside the display region. Therefore, the screen cannot be made into the pure circle, and the compensation effect is also significantly limited by the size of the frame.

### SUMMARY

The main objective of the present application is to provide an array substrate, aiming to improve the problem that the different lengths of the data lines in the same circular screen resulting in different loads, thereby causing different display brightness.

In order to achieve the above objective, the present application provides an array substrate, the array substrate has a circular display region, the display region is provided with data lines and scanning lines, the data lines and the scanning lines are insulated and intersected. There are at least two data lines, each of the data lines extends along a radial direction of the display region, the data lines are distributed at intervals along a circumferential direction of the display region. There are at least two circular scanning lines, and the scanning lines are provided to surround the circle center and are distributed along the radial direction of the display region.

In an embodiment, the display region is also provided with a plurality of sub-pixels, each of the sub-pixels has the same opening area, and is connected to the data line and the scanning line.

In an embodiment, an angle between two adjacent data lines is the same, and a distance between two adjacent scanning lines is increasing in a direction from an outer edge to the circle center of the display region.

In an embodiment, at least two sub-pixels distributed along the circumferential direction are connected to the same data line, and are connected to different scanning lines.

In an embodiment, the plurality of sub-pixels distributed along the circumferential direction are connected to the plurality of data lines in one-to-one correspondence, and are connected to the same scanning line.

In an embodiment, the array substrate further includes a chip on film (COF), the COF is circular in shape, concentric with the display region and has a plurality of pins, and each of the pins is connected to the data line.

In an embodiment, the array substrate further includes a non-display region, the non-display region is located on an inner side of the display region and concentric with the display region, the COF is provided in the non-display region, the non-display region has a through hole in a middle part, and the through hole is provided concentrically with the non-display region.

In an embodiment, the COF is provided on a side of the array substrate on which the data lines and the scanning lines are provided.

The present application also provides a display panel, and the display panel includes a color filter substrate and the array substrate described above. The color filter substrate is in a circular shape and is cell-aligned with the array substrate, and projection of the color filter substrate on the array substrate at least covers the display region. The data lines and the scanning lines are located on a side of the array substrate facing the color filter substrate.

The present application also provides a display device, the display device includes a backlight module and the display panel described above, and the backlight module is provided on a side of the array substrate away from the color filter substrate.

In the present application, by extending each of the data lines along the radial direction of the circular display region and making the extension lines of the data lines intersect at the circle center of the display region, the lengths of the data lines located in the display region can be set to be equal. Therefore, when driven at the same voltage, the display brightness can also be the same, avoiding adding a compensation line to obtain uniform display brightness and avoiding occupying too many regions other than the display region. As a result, the array substrate and the display screen can be truly made into the pure circle and realize narrow frames. By providing the scanning lines to surround the circle center of the display region and distribute along the radial direction of the display region, the scanning lines can intersect with each of the data lines, so that the pixel electrode on the array substrate can be connected to the data line and the scanning line.

### BRIEF DESCRIPTION OF THE DRAWINGS

In order to more clearly illustrate the technical solutions in the present application or related technologies, the following will briefly introduce the accompanying drawings that need to be used in the description of the embodiments or related technologies. Obviously, the accompanying drawings in the following description are some embodiments of the present application. For those skilled in the art, other drawings can also be obtained based on the structures shown in these drawings without any creative effort.

FIG. 1 is a top view of an array substrate according to an embodiment of the present application.

FIG. 2 is a top view of the array substrate after removing the data lines, scanning lines and chip on film (COF) according to an embodiment of the present application.

FIG. 3 is a projected partial view of the array substrate according to an embodiment of the present application.

FIG. 4 is a projected partial view of the array substrate according to another embodiment of the present application.

FIG. 5 is a schematic structural diagram of a display panel according to an embodiment of the present application.

FIG. 6 is a schematic structural diagram of a display device according to an embodiment of the present application.

The achievement of the purpose, functional characteristics and advantages of the present application will be further described with reference to the accompanying drawings in conjunction with embodiments.

### DETAILED DESCRIPTION OF THE EMBODIMENTS

The technical solutions of the embodiments of the present application will be described clearly and completely below with reference to the accompanying drawings. It is obvious that the embodiments to be described are only some rather than all of the embodiments of the present application. All other embodiments obtained by persons skilled in the art based on the embodiments of the present application without creative efforts shall fall within the scope of the present application.

It should be noted that if there are directional indications (such as up, down, left, right, front, back . . . ) in the embodiments of the present application, the directional indications are only used to explain the relative position relationship, motion situation and the like between components in a specific posture (as shown in the accompanying drawings). If the specific posture changes, the directional indication also changes accordingly.

In addition, if there are descriptions related to “first”, “second” and the like in the embodiments of the present application, the descriptions of “first”, “second” and the like are only for the purpose of description and cannot be understood as indicating or implying their relative importance or implying the number of technical features indicated. Thus, features defined as “first” and “second” may explicitly or implicitly include at least one of these features. In addition, the technical solutions of the various embodiments can be combined with each other, but must be based on what those skilled in the art can implement. When the combination of technical solutions is contradictory or cannot be realized, it should be considered that the combination of such technical solutions does not exist and is not within the scope of the present application.

The present application provides an array substrate 100.

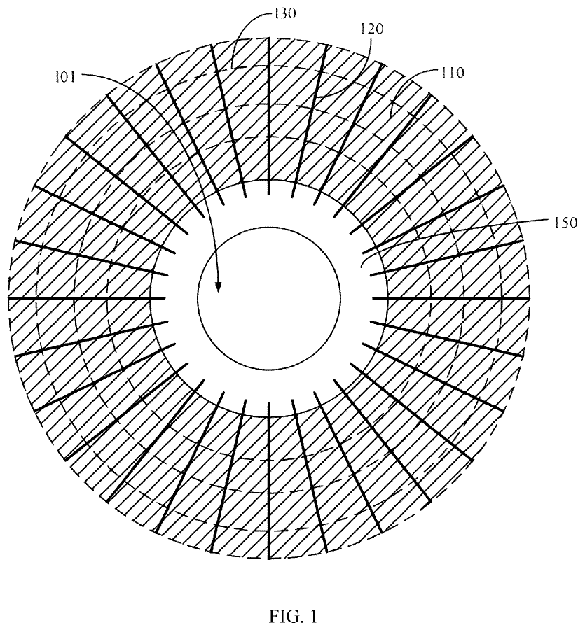

In the embodiment of the present application, as shown in FIG. 1, the array substrate 100 has a circular display region 110, the display region 110 is provided with data lines 120 and scanning lines 130, and the data lines 120 and the scanning lines 130 are insulated and intersected. There are at least two data lines 120, each of the data lines 120 extends along a radial direction of the display region 110, and the data lines 120 are distributed at intervals along a circumferential direction of the display region 110. There are at least two circular scanning lines 130, and the scanning lines 130 are provided to surround a circle center of the display region 110, and are distributed along the radial direction of the display region 110.

By providing the display region 110 of the array substrate 100 in a circular shape, the display region 110 has the circle center, and a length of a line segment that extends from the circle center to an outer edge of the display region 110, that is, the length of a radius of the display region 110, is equal. By extending the data lines 120 along the radial direction of the display region 110 and distributing the data lines 120 at intervals along the circumferential direction of the display region 110, intersection points of the extension lines of the data lines 120 meet at the circle center of the display region 110, making the lengths of the data lines 120 equal. By setting the lengths of the data lines 120 to be equal, the load on each data line 120 is equal, and when driven at the same voltage, the actual voltage on each data line 120 is also the same, resulting in the same display brightness. In addition, by extending the data line 120 along the radial direction of the display region 110, it is possible to reduce the arrangement of windings in areas other than the display region 110 while the lengths of the data lines 120 are ensured to be equal, thereby avoiding providing the data line 120 for compensation to obtain uniform display brightness and avoiding occupying too many regions other than the display region 110. Therefore, the array substrate 100 or the display screen can be truly made into the pure circle and realize narrow frames. Specifically, there may be two, three or more data lines 120, and the angles between two adjacent data lines 120 may be the same or different. The arrangement of all data lines 120 can be evenly spaced along the circumferential direction of the display region 110, or unevenly spaced as needs.

By providing the scanning line 130 in a circular shape and arranging the scanning lines 130 to surround the circle center and distribute along the radial direction of the display region 110, the scanning line 130 and the data line 120 can form an intersecting arrangement, which is easy for a pixel electrode on the array substrate 100 to be connected with both the scanning line 130 and the data line 120. Specifically, the spacing between two adjacent scanning lines 130 can be set to be the same or different.

In the technical solution of the present application, by extending each of the data lines 120 along the radial direction of the circular display region 110 and making the extension lines of the data lines 120 intersect at the circle center of the display region 110, the lengths of the data lines 120 located in the display region 110 can be set to be equal. Therefore, when driven at the same voltage, the display brightness can also be the same, avoiding adding a compensation line to obtain uniform display brightness and avoiding occupying too many regions other than the display region 110. As a result, the array substrate 100 and the display screen can be truly made into the pure circle and realize narrow frames. By providing the scanning lines 130 to surround the circle center of the display region 110 and distribute along the radial direction of the display region 110, the scanning lines 130 can intersect with each of the data lines 120, so that the pixel electrode on the array substrate 100 can be connected to the data line 120 and the scanning line 130.

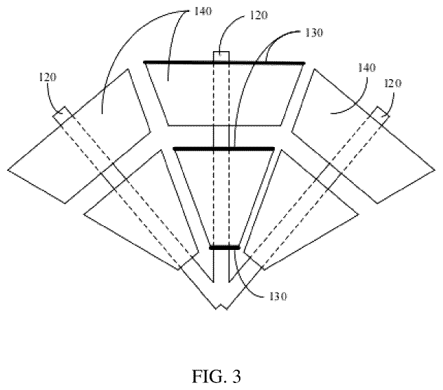

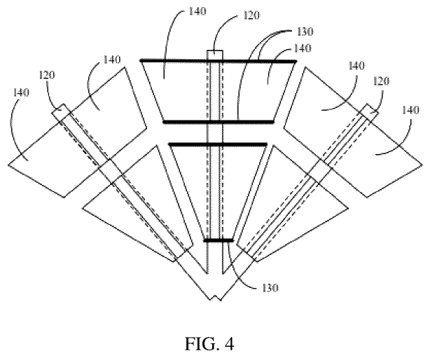

Further, as shown in FIG. 3 or FIG. 4, the display region 110 is further provided with a plurality of sub-pixels 140, each of the sub-pixels 140 has an equal opening area, and is connected to the data line 120 and the scanning line 130.

By setting the opening area of the sub-pixels 140 to be equal, the display device using the array substrate 100 can display more tones. Each of the sub-pixels 140 is connected to the data line 120 and the scanning line 130, the scanning line 130 acts as a switch, and the data line 120 transmits data signals for the sub-pixels 140.

Specifically, the shape of the sub-pixels 140 may be circular, rectangular, or trapezoidal. Based on the solution that the data line 120 extends along the radial direction of the display region 110 and the scanning line 130 is arranged in a circular shape, the shape formed by the intersection of the data line 120 and the scanning line 130 is substantially trapezoidal. Therefore, in an embodiment, the shape of the sub-pixels 140 is trapezoidal, thereby increasing the opening area of the sub-pixels 140 as much as possible and improving the luminous brightness. In order to ensure that the area of the sub-pixels 140 in the same radial direction is equal, the spacing between two adjacent scanning lines 130 can be changed, so that the spacing between two adjacent scanning lines 130 is different to ensure that the opening area of the sub-pixels 140 is equal. Alternatively, the sub-pixels 140 with the same area can be divided in the area defined by the intersection of the data line 120 and the scanning line 130, as long as the opening area of the sub-pixels 140 is equal.

Based on the solution that the opening area of the sub-pixels 140 is equal, in this embodiment, as shown in FIG. 1, FIG. 3 or FIG. 4, the angle between two adjacent data lines 120 is equal, and in a direction from the outer edge to the circle center of the display region 110, the distance between two adjacent scanning lines 130 is increasing.

By setting the angle between two adjacent data lines 120 to be equal, it is possible to ensure that the area of the regions defined by the intersection of the data line 120 and the scanning line 130 distributed in the same circumferential direction is equal, and it is possible to ensure that the area of the plurality of the sub-pixels 140 distributed along the circumferential direction can be set to be the same.

In addition, it can be understood that, by intersecting the scanning line 130 and the data line 120 and the scanning line 130 being a circle concentric with the display region 110, the lengths of the line segments of the scanning lines 130 connected between the two adjacent data lines 120 become shorter in the direction from the outer edge to the circle center of the display region 110. Therefore, the distance between two adjacent scanning lines 130 is increasing in the direction from the outer edge to the circle center of the display region 110, so that there is a possibility that the sub-pixels 140 in the same radial direction have the equal opening area. It can be understood that after the distance between the two outermost scanning lines 130 is determined, and the angle between two adjacent data lines 120 is also determined, the sub-pixel 140 is trapezoidal, and the opening area of the sub-pixel 140 as well as a short side and a long side of the sub-pixel 140 can be further determined.

Specifically, assuming that the specified opening area is S, the radius of the display region 110 is a, the angle between two adjacent data lines 120 is ca, and the trapezoidal height of an outermost sub-pixel 140 is h1, for the outermost sub-pixel 140: the short side is defined as X1 and the long side is defined as Y1, the short side X1=2*(a*sin β). Since S=(X1+Y1)*h1/2, Y1=(2S/h1)−X1=(2S/h1)−2*a*sinβ; and since tanP={(X1−Y1)/2}/h1, h1={(X1−Y1)/2}/tanβ, from Y1=(2S/h1)−X1=(2S/h1)−2*a*sinβ and h1={(X1−Y1)/2}/tanβ, the values of Y1 and h1 can be determined at the same time, and it is possible to determine the position of a second scanning line 130 in the direction from the outer edge to the circle center of the display region 110.

Further, since the distance between the sub-pixels 140 in a first lap near the outer edge of the display region 110 and the sub-pixels 140 in a second lap near the outer edge of the display region 110 is small and can be approximately ignored, it can be considered that Y1=X2. Therefore, when S is the same, the reason is the same:

since S=(Y1+Y2)*h2/2, h2=2S/(Y2+Y1); and since tanβ={(Y1−Y2)/2}/h2, h2={(X2−Y2)/2}/tanβ; from h2=2S/(Y2+Y1) and h2={(Y1-Y2)/2}/tanβ, the values of Y2 and h2 can be determined at the same time, and it is possible to determine the position of a third scanning line 130 in the direction from the outer edge to the circle center of display region 110. In a similar fashion, the height of h2˜h(n) and the long and short sides of each trapezoidal pixel can be accurately calculated from the above relationship. Therefore, the shape of the pixel can be determined, and the radius of the concentric circle of the scanning line 130 for each row can also be determined.

In an embodiment, as shown in FIG. 3, a plurality of sub-pixels 140 distributed along the circumferential direction and a plurality of data lines 120 are connected in one-to-one correspondence, and are connected with the same scanning line 130. Therefore, when the area of the display region 110 is constant and the number of data lines 120 is constant, the number of scanning lines 130 can be reduced, thereby increasing the area of the pixel region and increasing the aperture ratio.

Specifically, the data line 120 and the scanning line 130 can be respectively arranged on different sides of the sub-pixel 140 commonly controlled by both, that is, the projection of the data line 120 and the scanning line 130 on the surface of the array substrate 100 does not coincide with the projection of the sub-pixel 140. Alternatively, in other embodiments, the partial projection of the data line 120 on the surface of the array substrate 100 coincides with the partial projection of the sub-pixel 140.

In another embodiment, as shown in FIG. 4, at least two sub-pixels 140 distributed along the circumferential direction are connected to the same data line 120 and connected to different scanning lines 130.

The same data line 120 can connect two sub-pixels 140, three sub-pixels 140 or more sub-pixels 140 distributed along the circumferential direction. Specifically, the following is described as an example that the same data line 120 is connected to two sub-pixels 140 distributed along the circumferential direction. By connecting at least two sub-pixels 140 distributed along the circumferential direction to the same data line 120, under the premise of setting the same number of sub-pixels 140, the number of data lines 120 can be reduced, thereby increasing the area of the pixel region and increasing the aperture ratio. Specifically, in order to achieve the effect that at least two sub-pixels 140 distributed along the circumferential direction are connected to the same data line 120, the data line 120 can be provided between two adjacent sub-pixels 140, and each of the data lines 120 can be connected with two sub-pixels 140 distributed along the circumferential direction on both opposite sides. Further, it can be understood that each of the sub-pixels 140 is connected to the data line 120, so two different sub-pixels 140 distributed along the circumferential direction may be provided between two adjacent data lines 120, as a result, the two sub-pixels 140 distributed along the circumferential direction are respectively connected to the two data lines 120.

In addition, when the area of the display region 110 is constant and the number of data lines 120 is constant, by connecting the same data line 120 to at least two sub-pixels 140 distributed along the circumferential direction, the area of each sub-pixel 140 is made smaller, thereby realizing the effect of improving the resolution.

Further, based on the solution that at least two sub-pixels 140 distributed along the circumferential direction are connected to the same data line 120, in this embodiment, at least two sub-pixels 140 connected to the same data line 120 are also connected to different scanning lines 130, so that different control states for different sub-pixels 140 can be realized. Specifically, of at least two sub-pixels 140 distributed along the circumferential direction, a side away from the center of the display region 110 is provided with the scanning line 130, while a side close to the center of the display region 110 is provided with another scanning line 130. Therefore, two sub-pixels 140 distributed along the circumferential direction and connected to the same data line 120 can be respectively connected to the two scanning lines 130, so that at least two sub-pixels 140 distributed along the circumferential direction and connected to the same data line 120 can be connected to different scanning line 130.

In order to transmit data signals to the data line 120, in the technical solution of the present application, as shown in FIGS. 1, 2 and 5, the array substrate 100 also includes a chip on film (COF) 150. The COF 150 is circular in shape and is concentric with the display region 110. The COF 150 has a plurality of pins, and each of the data lines 120 is connected to the pin.

By arranging the COF 150 in the ring shape and concentric with the display region 110, the pin on the COF 150 connected to the data line 120 can be distributed on the COF 150 at intervals in the circumferential direction. Therefore, the distance between each of the pins and the data line 120 adjacent to thereof is equal, thereby further ensuring that the load on each data signal line is consistent, and improving the uniformity of the display. Specifically, the COF 150 can be provided inside or outside the display region 110.

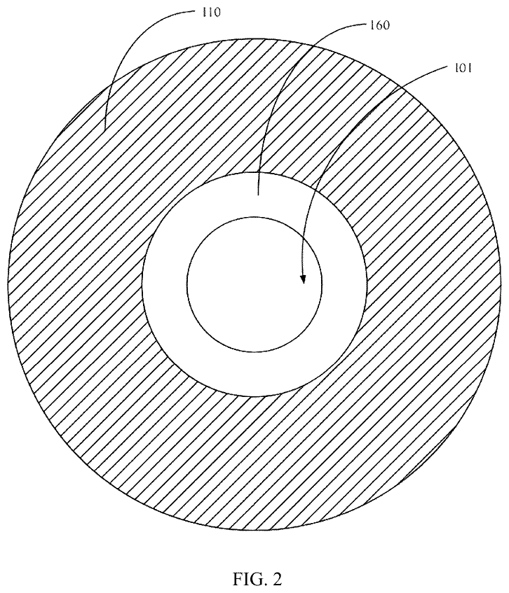

In this embodiment, as shown in FIG. 1 and FIG. 2, the array substrate 100 also has a non-display region 160110 on the inner side of the display region 110, and the non-display region 160110 is concentric with the display region 110. The COF 150 is provided in the non-display region 160110, a through hole 101 is provided in a middle of the non-display region 160110, and the through hole 101 is concentric with the non-display region 160110.

By providing the COF 150 in the non-display region 160110 concentric with the display region 110, it is possible to prevent arrangement of the COF 150 from affecting the display effect. In addition, by providing the non-display region 160110 on the inner side of the display region 110, on the one hand, the volume of the COF 150 can be set smaller, reducing production costs; on the other hand, it is also possible to obtain a better effect of narrow frame.

Further, the COF 150 is provided on a side of the array substrate 100 on which the data line 120 and the scanning line 130 are provided.

It can be understood that the pins on the COF 150 have a certain degree of softness, and can be operated such as bend. In this embodiment, by providing the COF 150 on the side of the array substrate 100 on which the data line 120 and the scanning line 130 are provided, when the COF 150 is connected to the PCB on the side of the array substrate 100 away from the data line 120 and the scanning line 130, it is possible to prevent the pins from breaking during the bending process of the pins on the COF 150 passing through a sidewall of the through hole 101 of the array substrate 100. If the data line 120 directly passes through the sidewall of the through hole 101 of the array substrate 100 and is bent, pins breakage is likely to occur since the data line 120 is a relatively hard metal sheet structure with poor toughness.

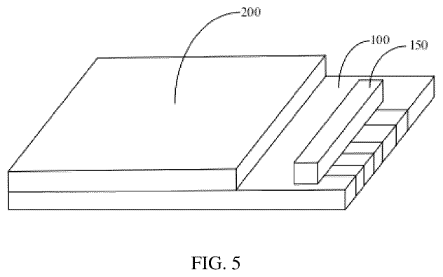

The present application also provides a display panel, as shown in FIG. 5, the display panel includes a color filter substrate 200 and the array substrate 100, and the specific structure of the array substrate 100 refers to the above-mentioned embodiments. Since the display panel adopts all the technical solutions of the above-mentioned embodiments, it has at least all the beneficial effects brought by the technical solutions of the above-mentioned embodiments, and the effects will not be repeated here. The color filter substrate 200 is in a circular shape and is cell-aligning with the array substrate 100, and projection of the color filter substrate 200 on the array substrate 100 covers at least the display region 110. The data line 120 and the scanning line 130 are located on the side of the array substrate 100 facing the color filter substrate 200.

By providing the color filter substrate 200 in the circular shape, the entire display panel is circular, so that the display panel can be adapted to application scenarios such as watches and oil dials. By making the projection of the color filter substrate 200 on the array substrate 100 cover at least the display region 110, the images displayed in the entire display region 110 can be displayed. Specifically, the area of the color filter substrate 200 may be the same as that of the display region 110, or may be larger than the area of the display region 110. Preferably, the area of the color filter substrate 200 can be set to be the same as the area of the display region 110, and when the non-display region 160110 is provided on the inner side of the display region 110, and the COF 150 is provided on the non-display region 160110, the color filter substrate 200 can be provided in parallel with the COF 150, therefore the thickness of the display panel can be reduced, and the effect of thinning the display panel can be obtained.

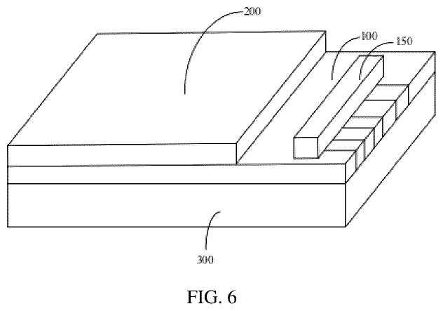

The present application also provides a display device. As shown in FIG. 6, the display device includes a backlight module 300 and a display panel. The specific structure of the display panel refers to the above-mentioned embodiments. Since this display device adopts all the technical solutions of the above-mentioned embodiments, it has at least all the beneficial effects brought by the technical solutions of the above-mentioned embodiments, and effects will not be repeated here. The backlight module 300 is provided on the side of the array substrate 100 away from the color filter substrate 200.

By providing the backlight module 300 on the side of the array substrate 100 away from the color filter substrate 200, the backlight module 300 is provided on a light-incident side of the array substrate 100, and the backlight module 300 can provide light for the array substrate 100, so that the display panel can display the images normally.

The above descriptions are only some embodiments of the present application, and are not intended to limit the scope of the present application. Under the inventive concept of the present application, any equivalent structural transformations made by using the contents of the description and the accompanying drawings of the present application, or directly/indirectly applications in other related technical fields, are included in the scope of the present application.

What is claimed is:

1. An array substrate, comprising a circular display region, wherein the display region is provided with at least two data lines and at least two scanning lines, the data lines and the scanning lines are insulated and intersected, each of the data lines extends along a radial direction of the display region, extension lines of the data lines intersect at a circle center of the display region, the data lines are distributed at intervals along a circumferential direction of the display region, and the scanning lines are provided to surround the circle center and are distributed along the radial direction of the display region.

2. The array substrate of claim 1, wherein the display region is also provided with a plurality of sub-pixels, each of the sub-pixels has the same opening area, and is connected to the data line and the scanning line.

3. The array substrate of claim 2, wherein an angle between two adjacent data lines is the same, and a distance between two adjacent scanning lines is increasing in a direction from an outer edge to the circle center of the display region.

4. The array substrate of claim 2, wherein the plurality of sub-pixels distributed along the circumferential direction are connected to the plurality of data lines in one-to-one correspondence, and are connected to the same scanning line.

5. The array substrate of claim 2, wherein at least two sub-pixels distributed along the circumferential direction are connected to the same data line, and are connected to different scanning lines.

6. The array substrate of claim 1, further comprising a chip on film (COF), wherein the COF is circular in shape, concentric with the display region and has a plurality of pins, and each of the pins is connected to the data line.

7. The array substrate of claim 6, further comprising a non-display region, wherein the non-display region is located on an inner side of the display region and concentric with the display region, the COF is provided in the non-display region, the non-display region has a through hole in a middle part, and the through hole is concentric with the non-display region.

8. The array substrate of claim 6, wherein the COF is provided on a side of the array substrate on which the data lines and the scanning lines are provided.

9. A display panel, comprising:
a color filter substrate; and
an array substrate comprising a circular display region, wherein the display region is provided with at least two data lines and at least two scanning lines, the data lines and the scanning lines are insulated and intersected, each of the data lines extends along a radial direction of the display region, extension lines of the data lines intersect at a circle center of the display region, the data lines are distributed at intervals along a circumferential direction of the display region, and the scanning lines are provided to surround the circle center and are distributed along the radial direction of the display region,
wherein the color filter substrate is in a circular shape and is cell-aligned with the array substrate, and the display region is at least covered by a projection of the color filter substrate on the array substrate, and the data lines and the scanning lines are located on a side of the array substrate facing the color filter substrate.

10. A display device, comprising:
a backlight module; and
a display panel, comprising:
a color filter substrate; and
an array substrate comprising a circular display region, wherein the display region is provided with at least two data lines and at least two scanning lines, the data lines and the scanning lines are insulated and intersected, each of the data lines extends along a radial direction of the display region, extension lines of the data lines intersect at a circle center of the display region, the data lines are distributed at intervals along a circumferential direction of the display region, and the scanning lines are provided to surround the circle center and are distributed along the radial direction of the display region,
wherein the color filter substrate is in a circular shape and is cell-aligned with the array substrate, and the display region is at least covered by a projection of the color filter substrate on the array substrate, and the data lines and the scanning lines are located on a side of the array substrate facing the color filter substrate, and
wherein the backlight module is provided on a side of the array substrate away from the color filter substrate.
